(19) United States
(12) Patent Application Publication
(10) Pub. No.: US 2014/0020926 A1
(43) Pub. Date: Jan. 23, 2014

(54) LEAD FRAME, LEAD FRAME ASSEMBLY AND METHOD OF CUTTING LEAD FRAME ASSEMBLY

(71) Applicant: DOW CORNING TAIWAN INC., TAIPEI (TW)

(72) Inventor: YA-CHING FENG, HSINCHU COUNTY (TW)

(21) Appl. No.: 13/933,690

(22) Filed: Jul. 2, 2013

(30) Foreign Application Priority Data
Jul. 20, 2012 (TW) 101214011
Sep. 26, 2012 (TW) 101218602
May 10, 2013 (CN) 201310172649.7

(51) Int. Cl. H01L 23/495; H01L 21/48

(52) U.S. Cl. CPC H01L 23/495; H01L 21/4821
USPC 174/68.1; 29/827

(57) ABSTRACT

A lead frame comprises a plurality of electrical connection portions, a frame portion, and a plurality of connections. The frame portion comprises a segment and at least one opening that defines the segment. Each connection connects to at least one of the plurality of electrical connection portions. The plurality of connections are arranged along a direction passing through the at least one opening and the segment. A dimension of the segment in the direction is less than 2.7 millimeters.

### CROSS-REFERENCE TO RELATED APPLICATION

The present application is based on, and claims priority from, Taiwan Patent Application Serial Number 101214011, filed on Jul. 20, 2012, Taiwan Patent Application Serial Number 101218602, filed on Sep. 26, 2012, and Chinese Patent Application Serial Number 201310172649.7, filed on May 10, 2013, the disclosure of which is hereby incorporated by reference herein in its entirety.

### BACKGROUND

1. Technical Field

The present invention relates to a lead frame, a lead frame assembly, and a method of cutting a lead frame assembly.

2. Related Art

A light-emitting diode device normally comprises a light-emitting diode and a lead frame. The lead frame may have two electrodes, wherein the two electrodes are electrically connected to the light-emitting diode, and the light-emitting diode is disposed on one of the two electrodes. The light-emitting diode device may further comprise a reflective cup surrounding the light-emitting diode. The reflective cup can outwardly reflect light laterally projected from the light-emitting diode.

Generally, in order to manufacture a light-emitting diode device, a lead frame strip is first prepared, which may comprise a plurality of lead frames arranged in a matrix. Next, reflective cups are correspondingly molded on the lead frame strip. Thereafter, light-emitting diodes are respectively attached onto lead frames and electrically connected to electrodes of corresponding lead frames via a wire-bonding process. Furthermore, resin is applied to encapsulate the light-emitting diodes.

In some processes of manufacturing light-emitting diode devices, high density lead frame strips are used. In a high density lead frame strip, lead frame members are separated by small gaps and compactly arranged so that reflective cups are integrated together after they are formed on the high density lead frame strip.

After light-emitting diodes are encapsulated by resin, a singulation process is then performed. During singulation, a blade cuts from a metal frame of a lead frame strip toward the connected reflective cups. The lead frame strip is of metal, while the reflective cups are of polymer. Since metal and polymer are different materials and have different hardnesses, they are usually cut by different methods. If they are cut by the same method, three types of deformities may occur after the blade initially cuts the metal by a distance and then cuts the polymer. These deformities consist of the connected reflective cups bulging up, large polymer fragments developing, or cracks forming in the reflective cups.

In addition, when reflective cups are molded on a high density lead frame strip, the reflective cups are connected together. Usually, the connected reflective cups deform the lead frame strip, which results in the difficulty of bonding light-emitting diodes and performing a wire-bonding process.

### SUMMARY

One embodiment of the present invention discloses a lead frame. The lead frame comprises a plurality of electrical connection portions, a frame portion, and a plurality of connections. The frame portion comprises a segment and at least one opening that defines the segment. Each connection connects to at least one of the plurality of electrical connection portions. The plurality of connections are arranged along a direction passing through the at least one opening and the segment. A dimension of the segment in the direction is less than 2.7 millimeters.

One embodiment of the present invention discloses a lead frame assembly. The lead frame assembly comprises a lead frame and an adhesive. The adhesive is attached to the lead frame. The lead frame comprises a frame portion, a plurality of electrical connection portions, and a plurality of connections. The frame portion comprises a segment and at least one opening that defines the segment. Each connection connects to at least one of the plurality of electrical connection portions, wherein the plurality of connections are arranged along a direction passing through the at least one opening and the segment. A dimension of the segment in the direction is less than 2.7 millimeters.

Another embodiment of the present invention discloses an additional lead frame. The additional lead frame comprises a frame portion. The frame portion comprises at least one opening and a segment. The at least one opening and the segment are arranged in a cutting direction. The at least one opening defines the segment. The segment has a dimension of less than 2.7 millimeters in the cutting direction.

Another embodiment of the present invention discloses a lead frame assembly. The lead frame assembly comprises the above-mentioned additional lead frame and an adhesive. The adhesive attaches to the additional lead frame.

One embodiment of the present invention discloses a method of cutting a lead frame assembly. The lead frame assembly comprises a lead frame and an adhesive. The adhesive is attached to the lead frame. The lead frame comprises a frame portion, a plurality of electrical connection portions, and a plurality of connections. The frame portion comprises a segment and at least one opening that defines the segment. Each connection connects to at least one of the plurality of electrical connection portions, wherein the plurality of connections are arranged along a direction passing through the at least one opening and the segment. A dimension of the segment in the direction is less than 2.7 millimeters. The method comprises: flatly securing the lead frame assembly; forming a cutting groove along the direction, wherein the groove is at least partially formed in the plurality of connections; and inspecting the warping of a cut lead frame assembly.

To provide a better understanding of the above-described objectives, characteristics, and advantages of the present invention, a detailed explanation is provided in the following embodiments with reference to the drawings.

### BRIEF DESCRIPTION OF THE DRAWINGS

The invention will be described according to the appended drawings in which:

FIG. 1 is a schematic view showing a lead frame according to one embodiment of the present invention;

FIG. 2 is a partially enlarged view of the lead frame of FIG. 1;

FIG. 3 is a schematic view showing a lead frame assembly according to one embodiment of the present invention;

FIG. 4 is a schematic view showing the back side of the lead frame assembly of FIG. 3;

FIG. 5 is a schematic view showing a lead frame according to another embodiment of the present invention;

FIG. 6 is a partially enlarged view of the lead frame of FIG. 5;

FIG. 7 is a schematic view showing a lead frame assembly according to one embodiment of the present invention;

FIG. 8 is a schematic rear view of the lead frame assembly of FIG. 7;

FIG. 9 is a schematic view showing a lead frame according to one embodiment of the present invention;

FIG. 10 is a partially enlarged view of the lead frame of FIG. 9;

FIG. 11 is a schematic view showing a lead frame according to another embodiment of the present invention;

FIG. 12 is a schematic view showing a lead frame assembly 3a according to one embodiment of the present invention;

FIG. 13 is a schematic side view showing a lead frame assembly 3a according to one embodiment of the present invention;

FIG. 14 is a cross-sectional view along line 3-3 of FIG. 12;

FIG. 15 is a schematic view showing a lead frame assembly according to one embodiment of the present invention;

FIG. 16 is a schematic view showing a lead frame assembly according to another embodiment of the present invention;

FIG. 17 is a schematic view showing a lead frame assembly according to another embodiment of the present invention;

FIG. 18 is a schematic view showing a lead frame assembly according to another embodiment of the present invention;

FIG. 19 is a schematic view showing a lead frame assembly 3f according to one embodiment of the present invention; and

FIG. 20 is a cross-sectional view along line 9-9 of FIG. 19.

### DETAILED DESCRIPTION OF DISCLOSED EMBODIMENTS

The following description is presented to enable any person skilled in the art to make and use the disclosed embodiments, and is provided in the context of a particular application and its requirements. Various modifications to the disclosed embodiments will be readily apparent to those skilled in the art, and the general principles defined herein may be applied to other embodiments and applications without departing from the spirit and scope of the disclosed embodiments. Thus, the disclosed embodiments are not limited to the embodiments shown, but are to be accorded the widest scope consistent with the principles and features disclosed herein.

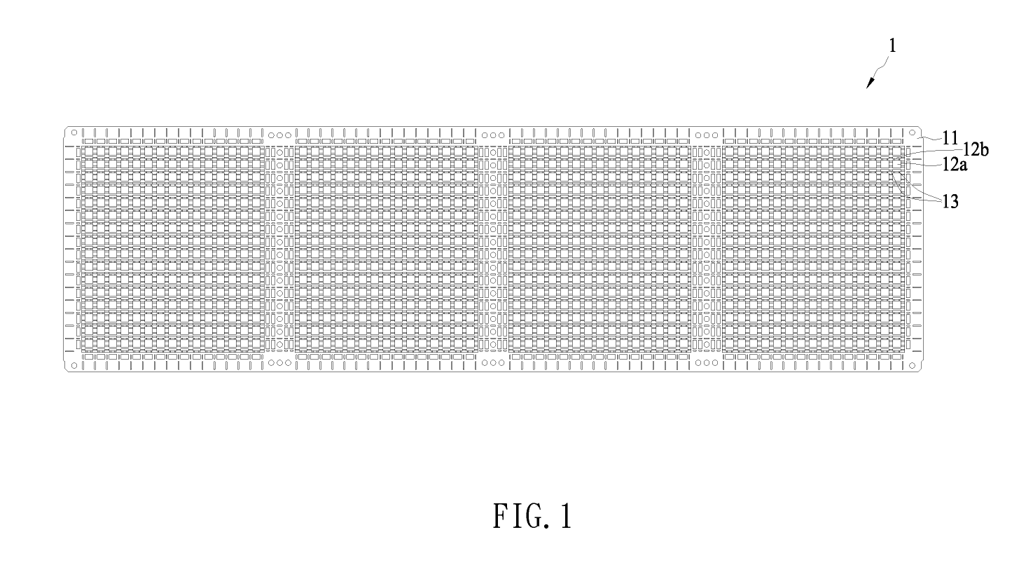

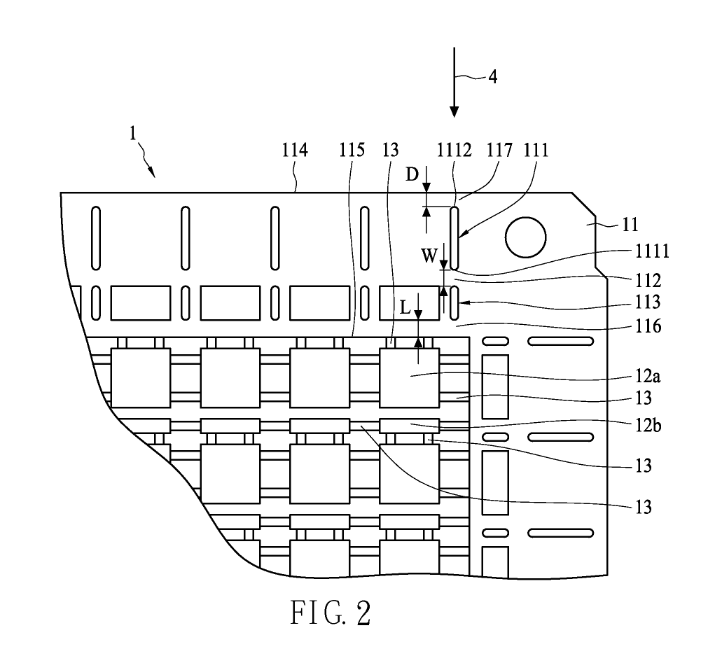

FIG. 1 is a schematic view showing a lead frame 1 according to one embodiment of the present invention. FIG. 2 is a partially enlarged view of the lead frame 1 of FIG. 1. Referring to FIGS. 1 and 2, the lead frame 1 comprises a frame portion 11, a plurality of electrical connection portions (12a and 12b), and a plurality of connections 13. The plurality of electrical connection portions (12a and 12b) may have a regular arrangement. The frame portion 11 may extend by the plurality of electrical connection portions (12a and 12b). Each connection 13 may connect to at least one electrical connection portion (12a or 12b).

In one embodiment, the lead frame 1 can have an enclosed frame body that externally surrounds the plurality of electrical connection portions (12a and 12b). A portion of the electrical connection portions (12a and 12b) connects to the enclosed frame body. The frame portion 11 may be a portion of the enclosed frame body, a frame edge of the enclosed frame body, or part of a frame edge of the enclosed frame body. In one embodiment, the frame portion 11 can extend between a plurality of electrical connection portions (12a and 12b).

In one embodiment, the lead frame 1 is configured for a light-emitting diode device, and the electrical connection portions (12a and 12b) are accordingly configured as electrodes for a light-emitting diode.

In one embodiment, two corresponding electrical connection portions (12a and 12b) can have different sizes, and the larger electrical connection portion (12a or 12b) is able to support a light-emitting diode.

Referring to FIG. 2, the electrical connection portions (12a and 12b) are mutually connected to each other or connected to the frame portion 11 using the connections 13. The connections 13 may be arranged in a plurality of rows and a plurality of columns. The frame portion 11 may comprise a plurality of first elongated openings or slots 111, which correspond to either the plurality of rows or columns of the connections 13. The first elongated opening 111 can be used for a singulation process; namely, during singulation, a saw blade may travel through the first elongated opening 111. A row or column of connections 13 are arranged in a direction 4 passing through a corresponding elongated opening 111, and the corresponding elongated opening 111 longitudinally extends along the direction 4 as well. The direction 4 may be a cutting direction which a saw blade follows during cutting.

Referring to FIG. 2, each first elongated opening 111 has two short edges (1111 and 1112), in which the short edge 1111 is closer to the electrical connection portions (12a and 12b) than the other short edge 1112. Each short edge 1111 is defined by a segment 112 of the frame portion 11.

A segment 112 is the part of the frame portion 11 that is located in a cutting direction and defined by an edge of an opening or edges of an opening and the frame portion 11. In one embodiment, the frame portion 11 comprises at least one segment (112, 116, or 117), wherein when a saw blade travels along the direction 4 during singulation, the saw blade will travel through the at least one segment (112, 116, or 117), the corresponding first elongated opening 111, and corresponding connections 13.

In one embodiment, each segment 112 defining the corresponding elongated opening 111 has a dimension “W”, measured in the direction 4 along which a corresponding row or column of connections 13 are arranged, of less than 2.7 millimeters. In one embodiment, the dimension “W” of the segment 112 is less than 2.5 millimeters. In one embodiment, the dimension “W” of the segment 112 is less than two millimeters. In one embodiment, the dimension “W” of the segment 112 is less than one millimeter. When the segment 112 has a larger dimension “W,” the frame portion 11 can be more rigid at the part where the segment 112 is located; when the segment 112 has a smaller dimension “W,” the frame portion 11 has less of a part needed to be cut; thus, avoiding the issues of cutting two different materials.

In one embodiment, the dimension “W” of the segment 112 is not less than a thickness of the frame portion 11, wherein the thickness of the frame portion 11 is measured in a direction perpendicular to the plane of FIG. 2. In one embodiment, the thickness of the frame portion 11 is measured at a predetermined point of the frame portion 11. In one embodiment, the thickness of the frame portion 11 is an average of the thicknesses measured at a plurality of certain points of the frame portion 11. In one embodiment, the thickness of the frame portion 11 is obtained by measuring the thickest part of the frame portion 11. In one embodiment, the thickness of the frame portion 11 is obtained by measuring the thinnest part of the frame portion 11. In one embodiment, the thickness of the frame portion 11 is between the measurement obtained from the thickest part of the frame portion 11 and the measurement obtained from the thinnest part of the frame portion 11. In one embodiment, the thickness of the frame portion 11 is between 0.1 millimeters and 0.5 millimeters.

Referring to FIG. 2, in one embodiment, the segment 117, arranged in the direction 4 as the connections 13 and formed next to an outer edge 114 of the frame portion 11, has a dimension “D” of less than 2.7 millimeters in the direction 4. In one embodiment, the dimension “D” of the segment 117 along the direction 4 may be less than 2.5 millimeters. In one embodiment, the dimension “D” of the segment 117 in the direction 4 may be less than two millimeters. In one embodiment, the dimension “D” of the segment 117 in the direction 4 may be less than one millimeter. In one embodiment, the dimension “D” of the segment 117 in the direction 4 may not be less than the thickness of the frame portion 11, wherein the thickness of the frame portion 11 is measured in a direction perpendicular to the plane of FIG. 2. When the dimension “D” is larger, the frame portion 11 can be more rigid at the part where the segment 117 is located; when the dimension “D” is smaller, the frame portion 11 has less of a part needed to be cut and the edge of a cutting blade will be abraded more slowly.

Referring again to FIG. 2, the frame portion 11 may further comprise a plurality of second elongated openings 113, which correspond to the plurality of first elongated openings 111. The segment 112 is formed between a corresponding first elongated opening 111 and a corresponding second elongated opening 113.

Referring to FIG. 2, the frame portion 11 can have an inner edge 115, which may connect to part of the electrical connection portions (12a and 12b). There are segments 116 that are formed next to the inner edge 115. In one embodiment, the dimension “L” of the segment 116 along the direction 4 is less than 2.7 millimeters. In one embodiment, the dimension “L” of the segment 116 along the direction 4 is less than 2.5 millimeters. In one embodiment, the dimension “L” of the segment 116 along the direction 4 is less than two millimeters. In one embodiment, the dimension “L” of the segment 116 along the direction 4 is less than one millimeter. In one embodiment, the dimension “L” of the segment 117 along the direction 4 may not be less than the thickness of the frame portion 11, wherein the thickness of the frame portion 11 is measured in a direction perpendicular to the plane of FIG. 2.

The lead frame 1 consists of a conductor. In one embodiment, the lead frame 1 comprises at least one metal. In one embodiment, the lead frame 1 comprises iron. In one embodiment, the lead frame 1 comprises nickel. In one embodiment, the lead frame 1 comprises silver. In one embodiment, the lead frame 1 comprise copper. In one embodiment, the lead frame 1 comprises alloy. In one embodiment, the lead frame 1 comprises nickel iron alloy. In one embodiment, the lead frame 1 comprises copper alloy. In one embodiment, the lead frame 1 comprises clad materials such as copper clad stainless steel or the like. In one embodiment, the lead frame 1 comprises a metal-coated material such as silver-coated copper material or the like. In one embodiment, the lead frame 1 may be of material other than metal. In one embodiment, the lead frame 1 comprises silicon.

In one embodiment, the lead frame 21 can have a thermal conductivity of greater than 400 W/mK. In one embodiment, the lead frame 21 can have a thermal conductivity between 300 W/mK and 400 W/mK. In one embodiment, the lead frame 21 can have a thermal conductivity of less than 300 W/mK.

In one embodiment, the lead frame 1 can be formed by an etch process. In one embodiment, the lead frame 1 can be formed by stamping.

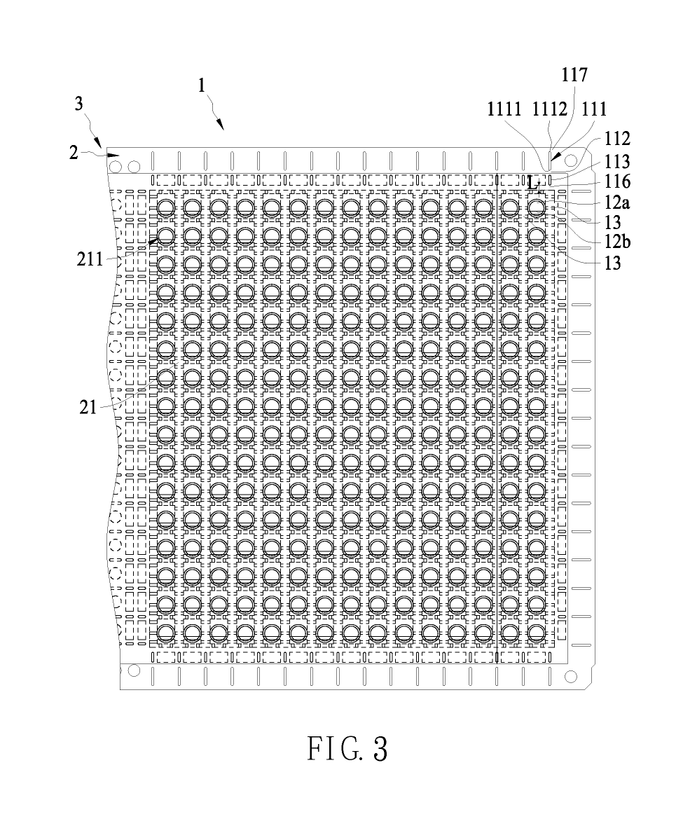

FIG. 3 is a schematic view showing a lead frame assembly 3 according to one embodiment of the present invention. As shown in FIG. 3, the lead frame assembly 3 comprises an afore-mentioned lead frame 1 and an adhesive 2 attached to the lead frame 1.

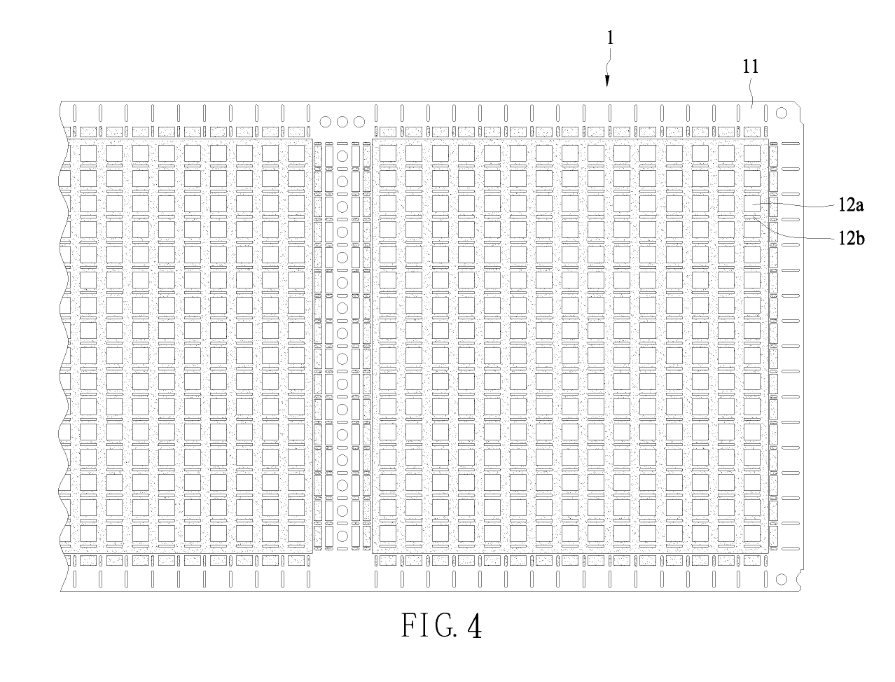

The adhesive 2 can fill the gaps between the electrical connection portions (12a and 12b) of the lead frame 1, as shown in the dotted regions of FIG. 4. In one embodiment, the adhesive 2 fills the second elongated openings 113 of the lead frame 1. In one embodiment, the adhesive 2 covers part of each segment 112.

The adhesive 2 comprises a main portion 21. The main portion 21 may protrude from the lead frame 1. The main portion 21 may be integrally formed. The main portion 21 may be formed with a plurality of recesses 211, in which each recess can receive a light-emitting diode. The recess 211 can be defined by an inclined or curved wall surface that can reflect light from a light-emitting diode.

The adhesive 2 may be a dielectric material. The adhesive 2 can have a high reflectivity in order to reflect light from a light-emitting diode. The adhesive 2 can be white. In one embodiment, the adhesive 2 may comprise epoxy. In one embodiment, the adhesive 2 may comprise silicone. In one embodiment, the adhesive 2 may comprise liquid crystal polymer, polyimide-based polymer, or the like.

In one embodiment, the adhesive 2 can be insert-molded to the lead frame 1. In one embodiment, the adhesive 2 attached to the lead frame 1 is formed by injection molding. In one embodiment, the adhesive 2 attached to the lead frame 1 is formed by a transfer molding process. In one embodiment, the adhesive 2 attached to the lead frame 1 is formed by a compression molding process.

Referring to FIG. 3, the adhesive 2 can be formed next to the segment 112. Since the segment 112 has a small size, the segment 112 can be near the first elongated openings 111 so that the adhesive 2 will not bulge up, nor generate any large polymer fragments, even if the same cutting method is used.

The lead frame can have a frame portion formed with another type of opening rather than the above-mentioned elongated openings.

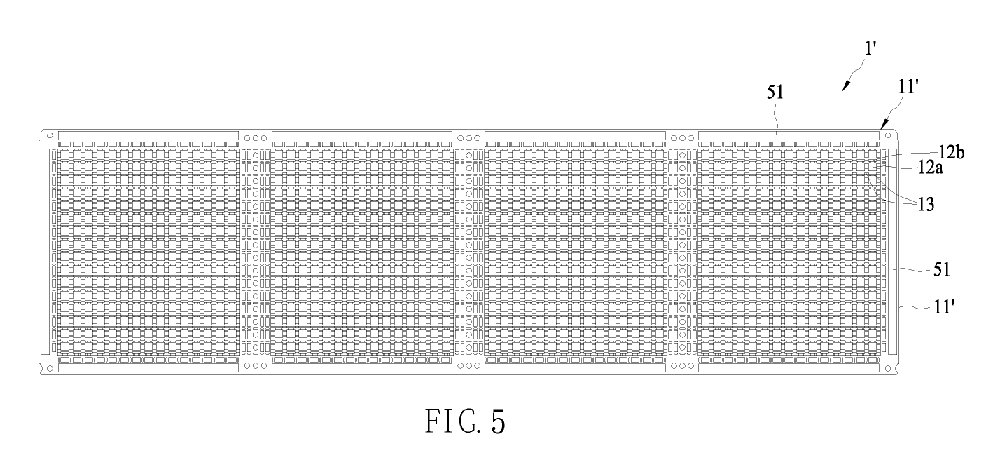

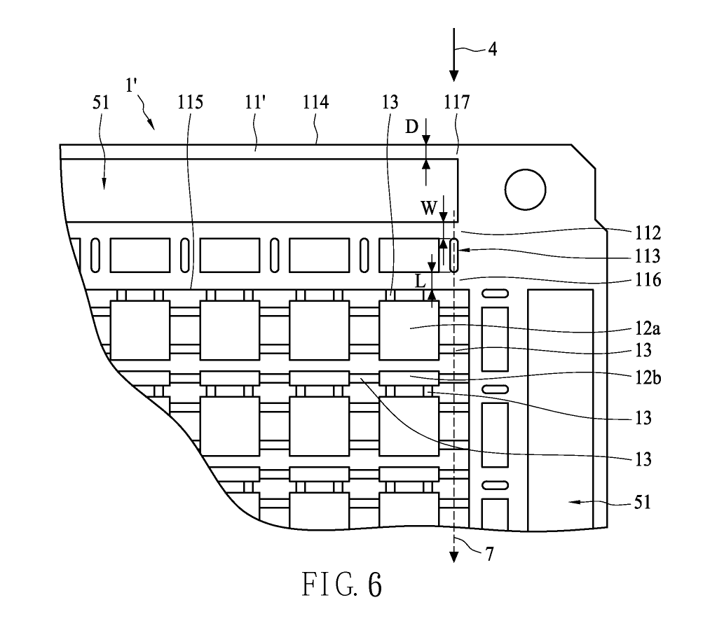

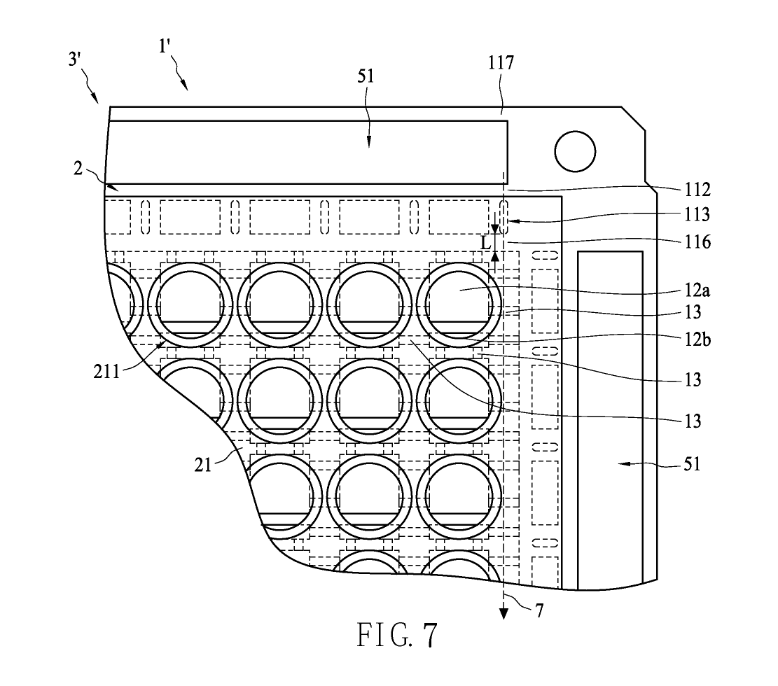

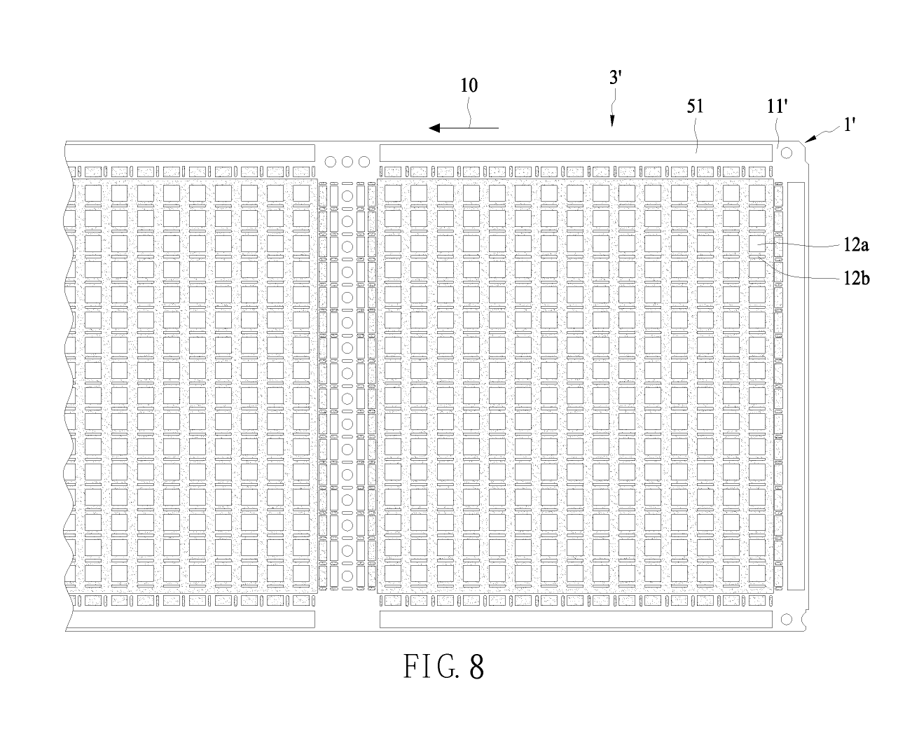

FIG. 5 is a schematic view showing a lead frame 1′ according to another embodiment of the present invention. FIG. 6 is a partially enlarged view of the lead frame 1′ of FIG. 5. FIG. 7 is a schematic view showing a lead frame assembly 3′ according to one embodiment of the present invention. FIG. 8 is a schematic rear view of the lead frame assembly 3′ of FIG. 7. Referring to FIGS. 5 and 6, the lead frame 1′ comprises a frame portion 11′ and a plurality of electrical connection portions (12a and 12b). A portion of electrical connection portions (12a and 12b) is connected to an inner edge 115 of the frame portion 11′ by the connections 13.

The frame portion 11′ can be a portion, a frame edge, or a portion of a frame edge of a frame body surrounding the plurality of electrical connection portions (12a and 12b). In one embodiment, the frame portion 11′ can extend between the plurality of electrical connection portions (12a and 12b).

The frame portion 11′ can be formed with a frame opening 51. The frame opening 51 may longitudinally extend in parallel to the outer edge 114 or inner edge 115 of the frame portion 11′ or extend along the longitudinal direction 10 of the frame portion 11′. The frame opening 51 can be used for singulation. Namely, during singulation, a saw blade may pass through the frame opening 51 and then move along a cutting path.

When the frame portion 11′ is a frame edge of a frame body, the frame portion 11′ can comprise a frame opening 51 that extends over the entire cutting range. In another embodiment, the frame portion 11′ may comprise a plurality of frame openings 51, in which each frame opening longitudinally extends in parallel to the outer edge 114 or inner edge 115 of the frame portion 11′. The plurality of frame openings 51 can have the same length or different lengths. The plurality of frame openings 51 can have the same width or different widths. The plurality of frame openings 51 can be aligned, or not aligned in a direction in parallel to the outer edge 114 or the inner edge 115.

The frame portion 11′ can comprise at least one segment (112, 116, or 117), wherein the frame opening 51 or the second elongated openings 113 defines the at least one segment (112, 116, or 117). The frame portion 11′ comprises a plurality of connections 13 that are arranged along a cutting direction 7 passing through the frame opening 51, a corresponding second elongated opening 113, and the at least one segment (112, 116, or 117).

Referring to FIG. 6, the frame opening 51 can be located adjacent to the outer edge 114 of the frame portion 11′. In one embodiment, the segment 117 formed between the frame opening 51 and the outer edge 114 of the frame portion 11′ can have a dimension “D” of less than 2.7 millimeters in a direction 4. In one embodiment, the dimension “D” of the segment 117 in the direction 4 is less than two millimeters. In one embodiment, the dimension “D” of the segment 117 in the direction 4 is less than one millimeter. In one embodiment, the dimension “D” of the segment 117 in the direction 4 is not less than the thickness of the frame portion 11′.

Referring to FIGS. 7 and 8, a lead frame assembly 3′ comprises the above-mentioned lead frame 1′ and an adhesive 2 attached to the lead frame 1′.

Referring to FIG. 7, the adhesive 2 comprises a main portion 21. The main portion 21 can protrude from the lead frame 1′. The main portion 21 can be formed with a plurality of recesses 211, in which each recess can receive a light-emitting diode. The wall surface that defines the corresponding recess 21 can be inclined or curved and is configured to reflect light from a light-emitting diode.

The adhesive 2 can be a dielectric material. The adhesive 2 can have a high reflectivity so as to reflect light from a light-emitting diode. The adhesive 2 can be white. In one embodiment, the adhesive 2 comprises epoxy. In one embodiment, the adhesive 2 comprises silicone. In one embodiment, the adhesive 2 comprises liquid crystal polymer, polyimide-based polymer, or the like.

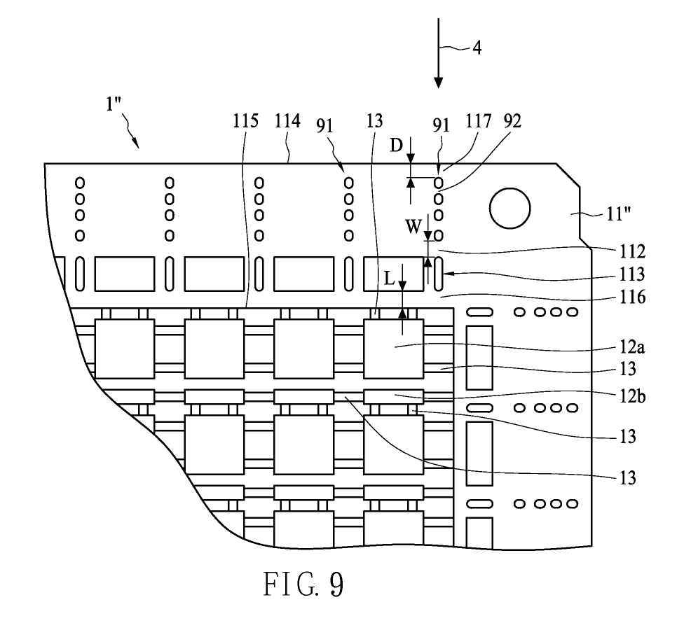

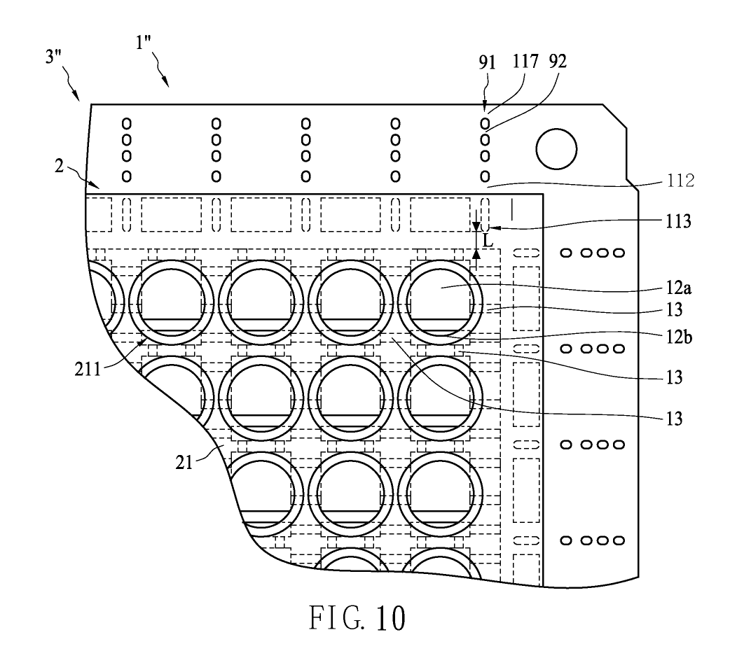

FIG. 9 is a schematic view showing a lead frame 1″ according to one embodiment of the present invention. FIG. 10 is a partially enlarged view of the lead frame 1″ of FIG. 9. Referring to FIGS. 9 and 10, the lead frame 1″ comprises a frame portion 11″. The frame portion 11″ may comprise at least one opening 91 and at least one segment (112, 116 or 117). The least one opening 91 is configured for singulation; namely, during singulation, a saw blade will travel along the at least one opening 91. A cutting direction 4 passes through the at least one opening 91 and the at least one segment (112, 116 or 117). In one embodiment, the at least one segment (112, 116 or 117) has a dimension (W, L, or D) of less than 2.7 millimeters in the direction 4. In one embodiment, the at least one segment (112, 116 or 117) has a dimension (W, L, or D) of less than 2.5 millimeters in the direction 4. In one embodiment, the at least one segment (112, 116 or 117) has a dimension (W, L, or D) of less than two millimeters in the direction 4. In one embodiment, the at least one segment (112, 116 or 117) has a dimension (W, L, or D) of less than one millimeter in the direction 4. In one embodiment, the dimension (W, L, or D) of the at least one segment (112, 116 or 117) in the direction 4 is not less than the thickness of the frame portion 11″, wherein the thickness of the frame portion 11″ is measured in a direction perpendicular to the plane of FIG. 9.

In one embodiment, the at least one opening 91 comprises a plurality of openings. In one embodiment, the at least one opening 91 comprises a plurality of openings arranged along the direction 4. In one embodiment, the at least one opening 91 comprises a plurality of openings in which the size of a portion of the openings is different from that of another portion of the openings. In one embodiment, the at least one opening 91 comprises a plurality of openings that have the same size. In one embodiment, the at least one opening 91 comprises a plurality of openings that are equally spaced from each other. In one embodiment, the at least one opening 91 comprises a plurality of openings that are not equally spaced from each other.

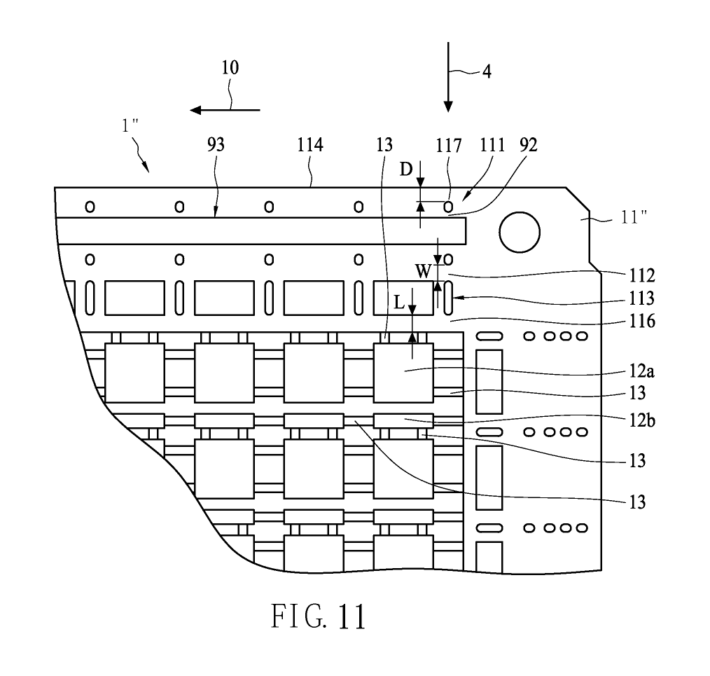

The at least one opening 91 comprises a plurality of openings. In one embodiment, as shown in FIG. 11, the plurality of openings comprises a frame opening 93 that longitudinally extends in parallel to the outer edge 115 or the inner edge 115 of the lead frame 1″ or along the longitudinal direction 10 of the lead frame 1″.

In one embodiment, the lead frame 1″ comprises a plurality of openings, wherein a segment 92 defined by a portion of the openings has a dimension of less than 2.7 millimeters in the direction 4. In one embodiment, the dimension of the segment 92 in the direction 4 is less than 2.5 millimeters. In one embodiment, the dimension of the segment 92 in the direction 4 is less than two millimeters. In one embodiment, the dimension of the segment 92 in the direction 4 is less than one millimeter. In one embodiment, the dimension of the segment 92 in the direction 4 is not less than the thickness of the frame portion 11″, wherein the thickness of the frame portion 11″ is measured in a direction perpendicular to the plane of FIG. 9.

In one embodiment, the at least one segment (112, 116 or 117) comprises a segment 117 that is located next to the outer edge 114 of the frame portion 11″.

The frame portion 11″ comprises an inner edge 115, to which a portion of the electrical connection portions (12a and 12b) are connected. In one embodiment, the at least one segment (112, 116 or 117) comprises a segment 116 that is located next to the inner edge 115 of the frame portion 11″.

Referring to FIG. 10, the lead frame 1″ may be attached to an adhesive 2 to form a lead frame assembly 3″. The adhesive 2 may fill the gaps between the electrical connection portions (12a and 12b). In one embodiment, the adhesive 2 may partially cover the segment 112.

In one embodiment of the present invention, at least one opening that divides part of the frame portion into a plurality of segments in a cutting direction is formed on a frame portion of a lead frame, thereby preventing an adhesive from being bulged up or generating large fragments during a cutting process. At least a portion of the segments have a dimension of less than a predetermined value, for example 2.7 millimeters or less, in the cutting direction.

A cutting method according to one embodiment of the present invention is demonstrated using an example having features similar to those of the embodiment of FIG. 3. However, the cutting method is not limited to such example. The cutting method can be applied to all the above embodiments and modifications or replacements that can be achieved according to the teachings and suggestions of the present disclosure.

Initially, the cutting method flatly secures a warped lead frame assembly. The lead frame assembly comprises a lead frame and an adhesive attached to the lead frame. The lead frame comprises a frame portion having a segment and at least one opening that defines the segment. The lead frame may further comprise a plurality of electrical connection portions and a plurality of connections, in which each connection connects to at least one electrical connection portion. The connections connect the plurality of electrical connection portions and the frame portion together. At least a portion of the connections are arranged along a direction passing through the at least one opening and the segment. The segment has a dimension of less than 2.7 millimeters in the direction.

Thereafter, the opening, the segment defined by the opening, and corresponding connections that are arranged in the direction are aligned with a cutting path. Next, a saw blade is applied to partially cut the lead frame assembly along the cutting path or direction, thereby forming a cutting grove. The cutting groove is formed at least into the corresponding connections. In one embodiment, the connections are broken off at the cutting groove. In another embodiment, the connections are broken off at the cutting groove while the frame portion is not broken off. Subsequently, the saw blade is applied to form other cutting grooves. In one embodiment, a portion of the cutting grooves intersect another portion of the cutting grooves. In another embodiment, the cutting grooves are parallel. Afterward, the cut lead frame assembly is inspected for warping.

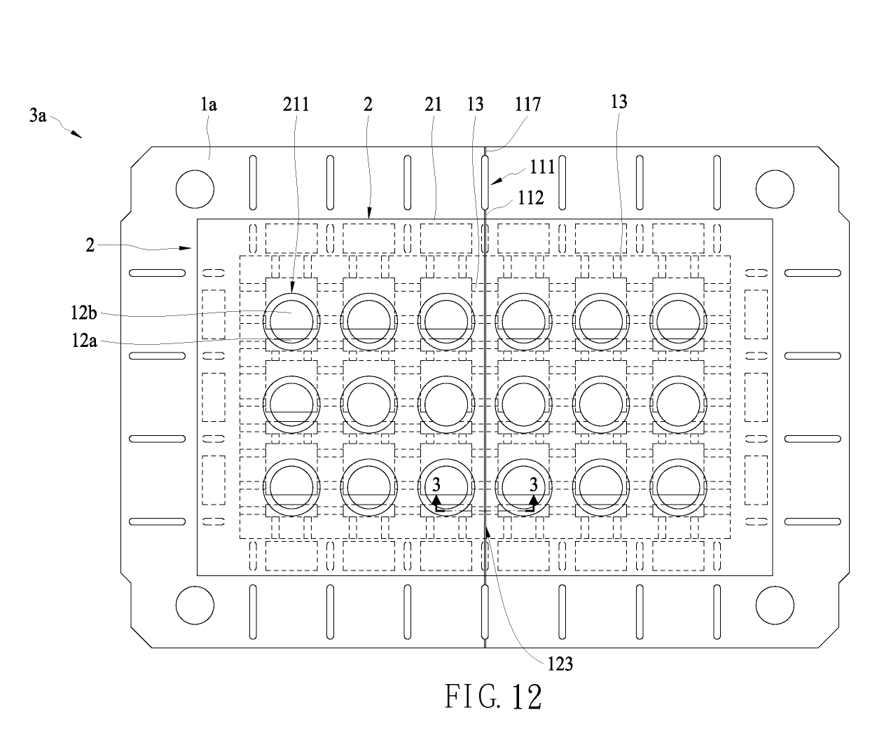

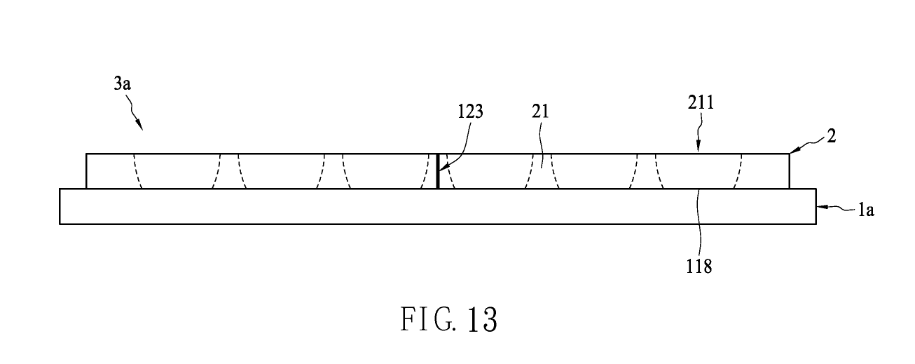

FIG. 12 is a schematic view showing a lead frame assembly 3a according to one embodiment of the present invention. FIG. 13 is a schematic side view showing a lead frame assembly 3a according to one embodiment of the present invention. Referring to FIGS. 12 and 13, a cutting tool is employed to cut the lead frame assembly 3a. The cutting tool forms a cutting groove 123 on the main portion 21 of an adhesive 2 of the lead frame assembly 3a. The cutting groove 123 may be formed across the main portion 21, thereby separating the main portion 21 into two split portions while the lead frame assembly 3a or the lead frame 1a is not broken off.

Specifically, after the adhesive 2 is molded, the main portion 21 of the adhesive 2 is attached to the surface of the lead frame 1a. Because the main portion 21 is integrally formed, the shrinkage of the main portion 21 causes the lead frame assembly 3a or the lead frame 1a to warp after the adhesive 2 is solidified. After a cutting groove 123 is formed on the main portion 21, the main portion 21 is separated into two portions such that the parts of the lead frame 1a on the two sides of the cutting groove are not pulled toward each other, and as a result, the warp of the lead frame 1a can be reduced.

In one embodiment, the cutting groove 123 is formed on the middle line of the connections 13. In one embodiment, the cutting groove 123 can be formed on a line of the connections 13 other than the middle line of the connections 13.

In one embodiment, the cutting groove 123 does not cause the corresponding connections 13 to break off. In one embodiment, the cutting groove 123 does cause the corresponding connections 13 to break off.

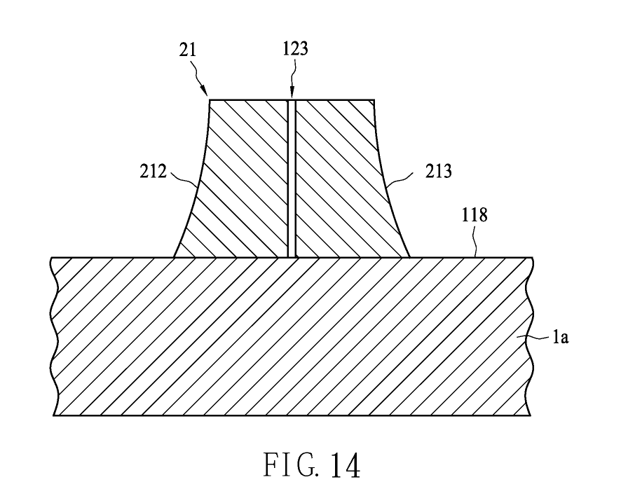

Referring to FIG. 14, the main portion 21 is separated by the cutting groove 123 into a plurality of split portions 212 and 213. In one embodiment, the cutting groove 123 is formed downward until the surface 118 of the lead frame 1a is reached so that the surface 118 of the lead frame 1a is exposed. In one embodiment, the cutting groove 123 is cut through the surface 118 such that the bottom of the cutting groove 123 is within the lead frame 1a.

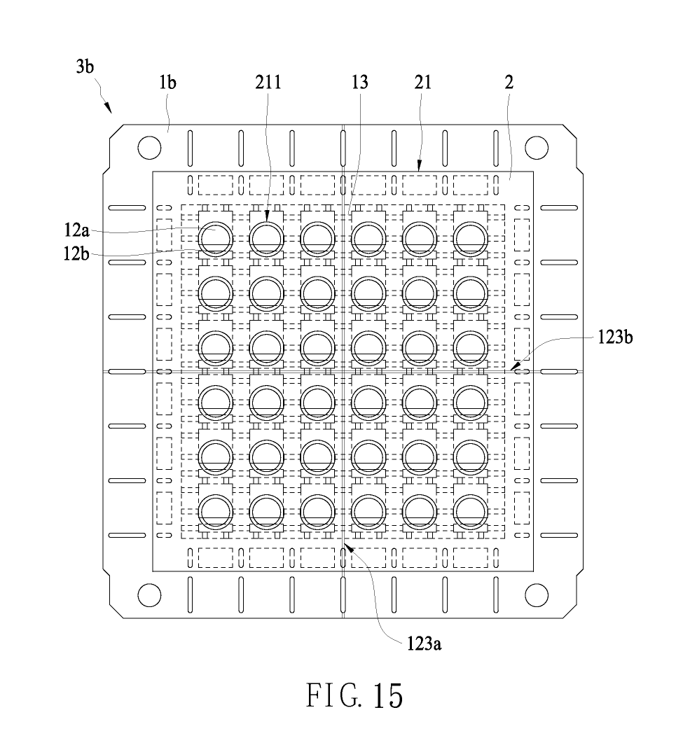

FIG. 15 is a schematic view showing a lead frame assembly 3b according to one embodiment of the present invention. As shown in FIG. 15, the lead frame assembly 3b comprises a lead frame 1b and an adhesive 2 attached to the lead frame 1b. The adhesive 2 comprises a main portion 21 integrally formed on the lead frame 1b. The main portion 21 may comprise a plurality of recesses, in which each recess can receive a light-emitting diode. The main portion 21 is cut to create two intersecting cutting grooves 123a and 123b, whereby the main portion 21 is separated into four split portions, and as a result, the warp of the lead frame assembly 3b can be reduced. In one embodiment, the cutting groove 123a is on the middle line of the connections 13. In one embodiment, the cutting groove 123a is on another line of the connections 13 rather than the middle line of the connections 13. In one embodiment, the cutting groove 123b is on the middle line of the connections 13. In one embodiment, the cutting groove 123b is on another line of the connections 13 rather than the middle line of the connections 13.

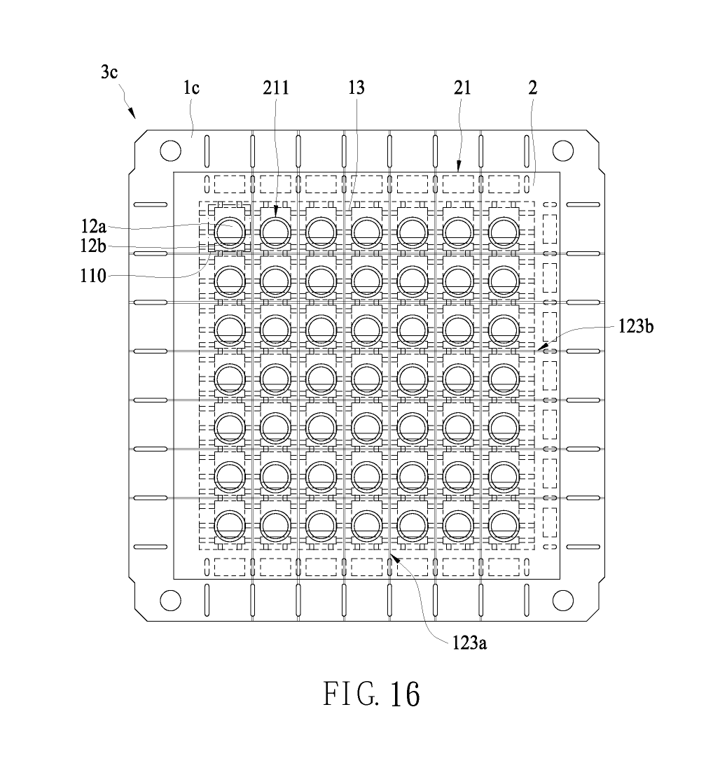

FIG. 16 is a schematic view showing a lead frame assembly 3c according to another embodiment of the present invention. As shown in FIG. 16, the lead frame assembly 3c comprises a lead frame 1c and an adhesive 2 attached to the lead frame 1c. The adhesive 2 comprises a main portion 21 integrally formed on the lead frame 1c. The main portion 21 may comprise a plurality of recesses, in which each recess can receive a light-emitting diode.

The main portion 21 is cut to create a plurality of cutting grooves 123a and a plurality of cutting grooves 123b, whereby the main portion 21 is separated into a plurality of split portions, and as a result, the warp of the lead frame assembly 3c can be reduced.

The plurality of cutting grooves 123a can be parallel. The plurality of cutting grooves 123b can be parallel. Each cutting groove 123a can extend between two rows of lead frame members 110, and each cutting groove 123b can extend between two columns of lead frame members 110. In one embodiment, a line of lead frame members 110 is between two adjacent cutting grooves 123a. In one embodiment, a line of lead frame members 110 is between two adjacent cutting grooves 123b.

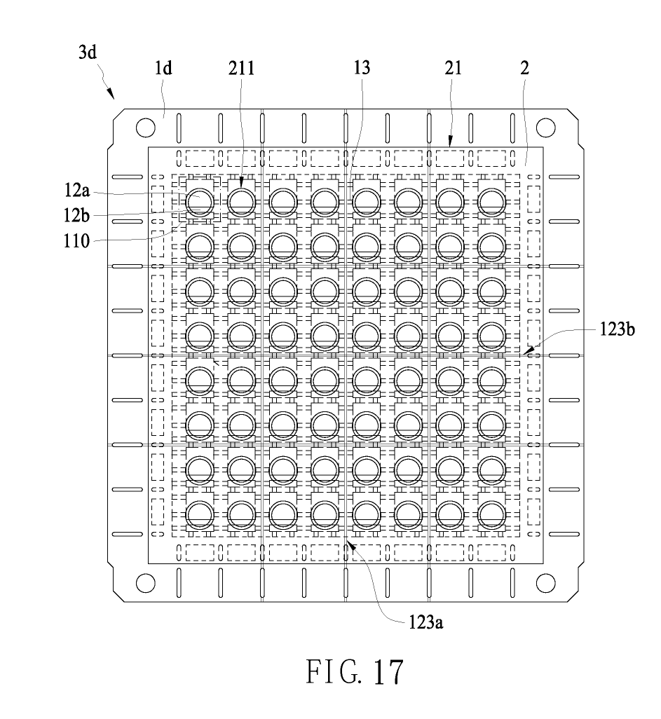

FIG. 17 is a schematic view showing a lead frame assembly 3d according to another embodiment of the present invention. Referring to FIG. 17, the lead frame assembly 3d comprises a lead frame 1d and an adhesive 2 attached to the lead frame 1d. The adhesive 2 comprises a main portion 21 integrally formed on the lead frame 1d. The main portion 21 may comprise a plurality of recesses, in which each recess can receive a light-emitting diode.

The main portion 21 is cut to create a plurality of cutting grooves 123a and a plurality of cutting grooves 123b, whereby the main portion 21 is separated into a plurality of split portions, and as a result, the warp of the lead frame assembly 3d can be reduced.

The plurality of cutting grooves 123a can be parallel. The plurality of cutting grooves 123b can be parallel. Each cutting groove 123a can extend between two rows of lead frame members 110, and each cutting groove 123b can extend between two columns of lead frame members 110. In one embodiment, two lines of lead frame members 110 are between two adjacent cutting grooves 123a. In one embodiment, two lines of lead frame members 110 are between two adjacent cutting grooves 123b.

Compared to the embodiment of FIG. 16, there are fewer cutting grooves 123a and 123b created in the embodiment of FIG. 17, which in turn reduces the number of cutting steps and lowers the manufacturing cost.

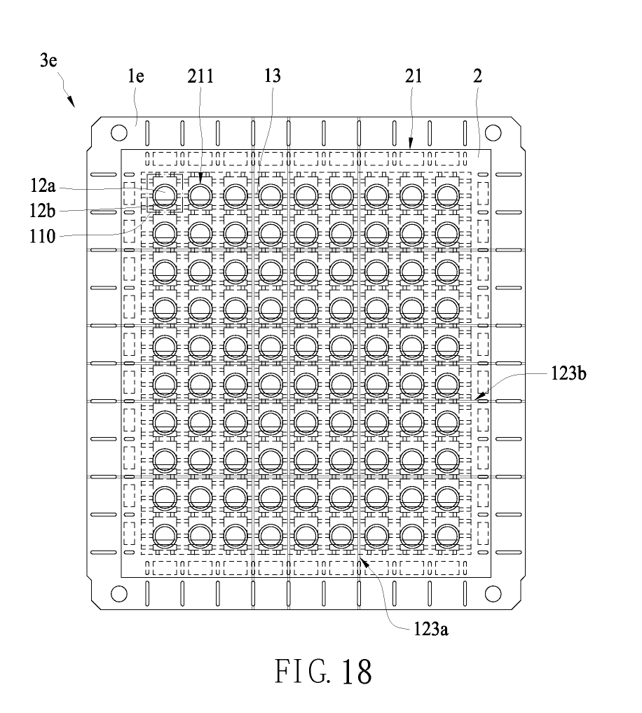

FIG. 18 is a schematic view showing a lead frame assembly 3e according to another embodiment of the present invention. Referring to FIG. 18, the lead frame assembly 3e comprises a lead frame 1e and an adhesive 2 attached to the lead frame 1e. The adhesive 2 comprises a main portion 21 integrally formed on the lead frame 1e. The main portion 21 may comprise a plurality of recesses, in which each recess can receive a light-emitting diode.

The main portion 21 is cut to create a plurality of cutting grooves 123a and a plurality of cutting grooves 123b, whereby the main portion 21 is separated into a plurality of split portions, and as a result, the warp of the lead frame assembly 3e can be reduced.

The plurality of cutting grooves 123a can be parallel. The plurality of cutting grooves 123b can be parallel. In one embodiment, in the row direction of the lead frame member arrangement, the cutting grooves 123a are spaced apart from each other by the same number of the lead frame members 110. In the present embodiment, the cutting grooves 123a are spaced apart from each other by three lead frame members 110. In one embodiment, the cutting grooves 123a and the cutting grooves 123b are respectively spaced by different numbers of lead frame members. In one embodiment, the cutting grooves 123b are not spaced from each other by a single number of lead frame members.

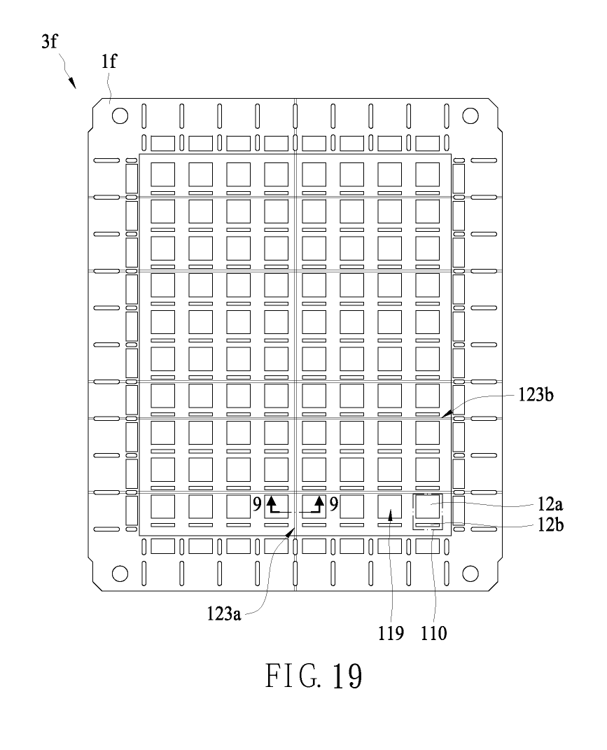

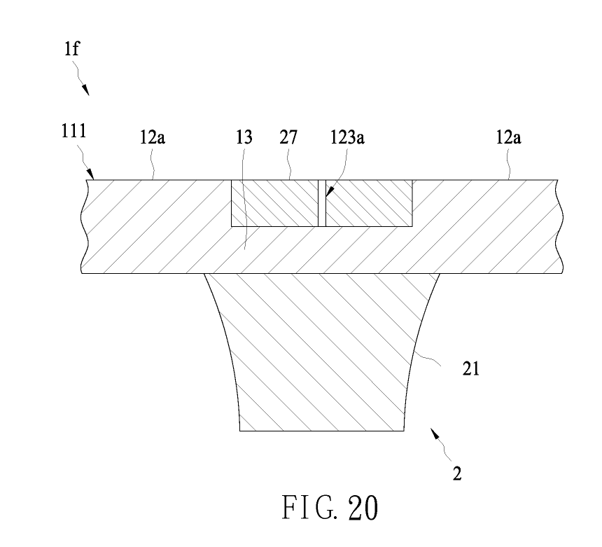

FIG. 19 is a schematic view showing a lead frame assembly 3f according to one embodiment of the present invention. FIG. 20 is a cross-sectional view along line 9-9 of FIG. 19. In some embodiments, another method of reducing the warp of a lead frame assembly is to create at least one cutting groove on the back side of the lead frame assembly 3f. Referring to FIGS. 19 and 20, in one embodiment, the lead frame assembly 3f comprises a lead frame if and an adhesive 2 attached to the lead frame 1f. The lead frame if has a back side 119. The adhesive 2 comprises an integrally formed main portion 21 that is formed opposite to the back side 119 of the lead frame if and protrudes from the lead frame 1f.

In one embodiment, at least one cutting groove 123a is created on the back side 119 of the lead frame 1f, and in particular, partially into the lead frame 1f. With the at least one cutting groove 123a, the warp of the lead frame if can be reduced. In one embodiment, a plurality of cutting grooves 123a are formed on the back side 119 of the lead frame 1f. In one embodiment, the cutting grooves 123a are parallel. In one embodiment, at least one line of lead frame members 110 extends between two adjacent cutting grooves 123a. In one embodiment, a plurality of lines of lead frame members 110 extend between two adjacent cutting grooves 123a. In one embodiment, the cutting grooves 123a are equally spaced apart from each other. In one embodiment, the cutting grooves 123a are not equally spaced apart from each other.

In one embodiment, at least one cutting groove 123b may be further created on the back side 119 of the lead frame 1f, thereby reducing the warp of the lead frame 1f. The at least one cutting groove 123b can be formed partially into the lead frame 1f. In one embodiment, the at least one cutting groove 123a and the at least one cutting groove 123b are intersecting.

In one embodiment, a plurality of cutting grooves 123a and one cutting groove 123b are formed on the back side 119 of the lead frame 1f.

In one embodiment, a plurality of cutting grooves 123b are formed on the back side 119 of the lead frame 1f. In one embodiment, the plurality of cutting grooves 123b are parallel. In one embodiment, at least one line of lead frame members 110 extends between two adjacent cutting grooves 123b. In one embodiment, a plurality of lines of lead frame members 110 extend between two adjacent cutting grooves 123b. In one embodiment, the cutting grooves 123b are equally spaced apart from each other. In one embodiment, the cutting grooves 123b are not equally spaced apart from each other.

In one embodiment, the cutting grooves 123a are spaced by a distance similar to that by which the cutting grooves 123b are spaced. In one embodiment, the cutting grooves 123a are spaced by a distance different from that by which the cutting grooves 123b are spaced. In one embodiment, part of cutting grooves 123a are spaced by a distance similar to that by which part of the cutting grooves 123b are spaced.

Referring to FIG. 20, the lead frame if comprises a plurality of connections 13, which can either connect adjacent electrical connection portions (12a and 12b) or connect electrical connection portions (12a and 12b) and the frame portion of the lead frame 1f. The adhesive 2 comprises a lower filling portion 27 that is formed adjacent to the back side 119 of the lead frame if and located below corresponding connections 13. In one embodiment, the cutting groove 123a or 123b is formed to separate the lower filling portion 27, but not into the corresponding line of connections 13. In one embodiment, the cutting groove 123a or 123b is formed into the corresponding line of connections 13. In one embodiment, the cutting groove 123a or 123b causes the corresponding line of connections 13 to break off.

In some embodiments of the present invention, the warp of a lead frame assembly can be reduced by using a cutting tool to cut the lead frame assembly without breaking the lead frame assembly. As a result, the cut lead frame assembly is suitable for bonding chips and wire-bonding. The cut lead frame assembly is integrally connected by the lead frame or an adhesive such that the cut lead frame can be conveniently handled in subsequent processes. A change is made to openings of a frame portion to cause segments defined by the openings to become smaller; for example, by less than 2.7 millimeters. Consequently, the adhesive will not easily bulge up or generate large fragments during a cutting process. In some embodiments, the above-mentioned segment is smaller to the extent that the opening of the frame portion is at a shorter distance from the adhesive. As a result, the adhesive will not bulge up or generate large fragments during a cutting process. In some embodiments, creating at least one shallow cutting groove formed on a lead frame assembly can reduce the warp of the lead frame assembly.

It will be apparent to those skilled in the art that various modifications can be made to the disclosed embodiments. It is intended that the specification and examples be considered as exemplary only, with the true scope of the disclosure being indicated by the following claims and their equivalents.

What is claimed is:

1. A lead frame comprising:
a plurality of electrical connection portions;
a frame portion comprising a segment and at least one opening that defines the segment; and
a plurality of connections, with each connecting to at least one of the plurality of electrical connection portions, wherein the plurality of connections are arranged along a direction passing through the at least one opening and the segment, wherein a dimension of the segment in the direction is less than 2.7 millimeters.

2. The lead frame of claim 1, wherein the dimension of the segment in the direction is between a thickness of the frame portion and 2.5 millimeters.

3. The lead frame of claim 1, wherein the segment is arranged next to an outer or inner edge of the frame portion, wherein a portion of the plurality of connections connect to the inner edge.

4. The lead frame of claim 1, wherein the at least one opening comprises a slot having a longitudinal axis extending in the direction, a frame opening extending along a longitudinal direction of the frame portion, or a plurality of openings arranged along the direction.

5. A lead frame assembly comprising:
a lead frame comprising:
a frame portion comprising a segment and at least one opening that defines the segment;
a plurality of electrical connection portions; and
a plurality of connections, with each connecting to at least one of the plurality of electrical connection portions, wherein the plurality of connections are arranged along a direction passing through the at least one opening and the segment, wherein a dimension of the segment in the direction is less than 2.7 millimeters; and
an adhesive attached to the lead frame.

6. The lead frame assembly of claim 5, wherein the dimension of the segment in the direction is between a thickness of the frame portion and 2.5 millimeters.

7. The lead frame assembly of claim 5, wherein the segment is arranged next to an outer edge of the frame portion, an inner edge of the frame portion, or the adhesive, wherein a portion of the plurality of connections connect to the inner edge.

8. The lead frame assembly of claim 5, wherein the at least one opening comprises a slot having a longitudinal axis extending in the direction, a frame opening extending along a longitudinal direction of the frame portion, or a plurality of openings arranged along the direction.

9. The lead frame assembly of claim 5, wherein the adhesive comprises a main portion protruding from the lead frame and formed with a plurality of recesses.

10. The lead frame assembly of claim 5, wherein the adhesive comprises silicone or epoxy.

11. A lead frame comprising:
a frame portion comprising at least one opening and a segment that are arranged in a cutting direction, wherein the at least one opening defines the segment, and the segment has a dimension of less than 2.7 millimeters in the cutting direction.

12. The lead frame of claim 11, wherein the dimension of segment is between a thickness of the frame portion and 2.5 millimeters in the cutting direction.

13. The lead frame of claim 11, wherein the segment is arranged next to an outer or inner edge of the frame portion; wherein the frame portion comprises a plurality of electrical connection portions connecting to the inner edge.

14. The lead frame of claim 11, wherein the at least one opening comprises a slot having a longitudinal axis extending in the cutting direction, a frame opening extending along a longitudinal direction of the frame portion, or a plurality of openings arranged along the cutting direction.

15. A lead frame assembly comprising:
a lead frame comprising a frame portion, wherein the frame portion comprises at least one opening and a segment that are arranged along a cutting direction, wherein the at least one opening defines the segment, and the segment comprises a dimension of less than 2.7 millimeters in the cutting direction; and
an adhesive attached to the lead frame.

16. The lead frame assembly of claim 15, wherein the dimension of the segment is between a thickness of the frame portion and 2.5 millimeters in the cutting direction.

17. The lead frame assembly of claim 15, wherein the segment is arranged next to an outer edge of the frame portion, an inner edge of the frame portion, or the adhesive, wherein the lead frame comprises a plurality of electrical connection portions connecting to the inner edge.

18. The lead frame assembly of claim 15, wherein the at least one opening comprises a slot having a longitudinal axis extending in the cutting direction, a frame opening extending along a longitudinal direction of the frame portion, or a plurality of openings arranged along the cutting direction.

19. The lead frame assembly of claim 15, wherein the adhesive comprises a main portion protruding from the lead frame and formed with a plurality of recesses.

20. The lead frame assembly of claim 15, wherein the adhesive comprises silicone or epoxy.

21. A method of cutting a lead frame assembly of claim 5, comprising:
flatly securing the lead frame assembly;
forming a cutting groove along the direction, wherein the groove is at least partially formed in the plurality of connections; and
inspecting a cut lead frame assembly for warping.

22. The method of claim 21, wherein the step of forming a cutting groove along the direction comprises a step of partially cutting into the lead frame assembly in the direction and cutting off the plurality of connections.

23. The method of claim 21, wherein the step of forming a cutting groove along the direction comprises a step of partially cutting into the lead frame assembly in the direction and cutting off the plurality of connections, but not cutting off the frame portion.

24. The method of claim 21, wherein the adhesive of the lead frame assembly comprises a main portion formed with a plurality of recesses, wherein the cutting groove separates the main portion.

25. The method of claim 21, wherein the adhesive of the lead frame assembly comprises a main portion formed with a plurality of recesses and a back side opposite to the main portion, wherein the cutting groove is formed on the back side.
